(19) United States
(12) Patent Application Publication
(10) Pub. No.: US 2014/0338962 A1
(43) Pub. Date: Nov. 20, 2014

(54) GRAPHENE AND HEXAGONAL BORON NITRIDE PLANES AND ASSOCIATED METHODS

(71) Applicant: Chien-Min Sung, Tansui (TW)

(72) Inventor: Chien-Min Sung, Tansui (TW)

(21) Appl. No.: 14/231,443

(22) Filed: Mar. 31, 2014

Related U.S. Application Data
(63) Continuation of application No. 14/155,305, filed on Jan. 14, 2014.
Application No. 14/155,305 is a continuation of application No. 12/499,647, filed on Jul. 8, 2009, now abandoned.
(60) Provisional application No. 61/079,064, filed on Jul. 8, 2008.
(60) Provisional application No. 61/145,707, filed on Jan. 19, 2009.

(51) Int. Cl. C01B 31/04; H05K 1/03; C01B 21/064

(52) U.S. Cl. CPC C01B 31/0446; C01B 21/0648; H05K 1/0353
USPC 174/255; 423/448; 252/71; 423/290; 428/408

(57) ABSTRACT

Graphene layers, hexagonal boron nitride layers, as well as other materials made of primarily sp2 bonded atoms and associated methods are disclosed. In one aspect, for example, a method of forming a graphene layer is provided. Such a method may include mixing a carbon source with a horizontally oriented molten solvent, precipitating the carbon source from the molten solvent to form a graphite layer across the molten solvent, and separating the graphite layer into a plurality of graphene layers.

### PRIORITY DATA

This application is a continuation of U.S. patent application Ser. No. 14/155,305, filed Jan. 14, 2014, which is a continuation of U.S. patent application Ser. No. 12/499,647, filed Jul. 8, 2009, which claims the benefit of U.S. Provisional Patent Application Ser. No. 61/079,064, filed on Jul. 8, 2008 and U.S. Provisional Patent Application Ser. No. 61/145,707, filed on Jan. 19, 2009, each of which are incorporated herein by reference.

### FIELD OF THE INVENTION

The present invention relates generally to graphene and hexagonal boron nitride planes and associated methods. Accordingly, the present invention involves the chemical and material science fields.

### BACKGROUND OF THE INVENTION

Graphene is often defined as a one-atom-thick planar sheet of sp2-bonded carbon atoms that are densely packed into a benzene-ring structure in a honeycomb crystal lattice. This two-dimensional material exhibits high electron mobility in the plane of the layer, as well as exceptional thermal conductivity. Graphite is comprised of multiple layers of graphene stacked parallel to one another.

Graphene is widely used to describe properties of many carbon-based materials, including graphite, large fullerenes, nanotubes, etc. For example, carbon nanotubes may be described as graphene sheets rolled up into nanometer-sized cylinders. Furthermore, planar graphene itself has been presumed not to exist in the free state, being unstable with respect to the formation of curved structures such as soot, fullerenes, and nanotubes.

Attempts have been made to incorporate graphene into electronic devices such as transistors, however such attempts have generally been unsuccessful due to problems associated with the production of high quality graphene layers of a size suitable for incorporation into such devices. One technique for generating graphene layers involves peeling graphene planes from highly oriented pyrolitic graphite. Using such methods, only small flakes are produced that are generally too small to be utilized in electronic applications.

### SUMMARY OF THE INVENTION

Accordingly, the present invention provides graphene and hexagonal boron nitride layers and associated methods thereof. In one aspect, for example, a method of forming a graphene layer is provided. Such a method may include mixing a carbon source with a horizontally oriented molten solvent, precipitating the carbon source from the molten solvent to form a graphite layer across the molten solvent, and separating the graphite layer into a plurality of graphene layers. In some aspects, a single graphene layer may be precipitated on the surface of the molten solvent catalyst material and then either harvested or used as a composite device after the catalyst material has been cooled. In another aspect, mixing the carbon source with the molten solvent includes applying the carbon source to a solidified solvent layer, and heating the solidified solvent layer under vacuum to melt the solidified solvent layer into a molten solvent such that the molten solvent and carbon atoms from the carbon source form a eutectic liquid. In yet another aspect, precipitating the carbon source from the molten solvent includes maintaining the molten solvent and the carbon source in a eutectic liquid state to allow the graphite layer to form across substantially all of the molten solvent. Non-limiting examples of carbon sources include graphite, highly graphitized graphite, diamond, and the like. It should be noted that the scope of the present invention also includes graphene materials made according to aspects described herein.

In one aspect of the present invention, the molten solvent can include materials such as Cr, Mn, Fe, Co, Ni, Ta, Pd, Pt, La, Ce, Eu, associated alloys, and combinations thereof. In one specific aspect, the molten solvent can include Ni. In another specific aspect the molten solvent can comprise substantially Ni, and in some aspects may consist of Ni or a Ni alloy. In some aspects, materials can be included in the molten solvent to reduce reactivity. In one aspect, for example, the molten solvent can include a substantially less reactive compound, where the substantially less reactive compound reduces the reactivity of the molten solvent as compared to the molten solvent without the substantially less reactive compound. Although any compound that reduces the reactivity of the molten solvent can be utilized, in one aspect the substantially less reactive compound can be selected from Au, Ag, Cu, Pb, Sn, Zn, and combinations and alloys thereof. In one specific aspect, the substantially less reactive compound is Cu.

In some aspects it can be beneficial to utilize a high quality of graphite for the construction of graphene layers. In one aspect, therefore, it may be beneficial to substantially remove impurities from the graphite. While any impurity may be removed that has undesirable effects on the properties of the graphene material, in one specific aspect the impurities removed may include O, N, or a combination thereof.

It is also contemplated that the graphene layer may be doped with a dopant. It should be noted that a variety of dopants can be included in the graphene layer, depending on the desired properties of the resultant material. In one aspect, for example, the dopant can include an element such as B, Be, P, N, or a combination of such elements. In another aspect, the dopant can be a metal atom.

The present invention additionally provides hexagonal boron nitride layers and associated methods thereof. In one aspect, for example, a method of forming a hexagonal boron nitride layer is provided. Such a method may include mixing a boron nitride source with a horizontally oriented molten solvent and precipitating the boron nitride source from the molten solvent to form a hexagonal boron nitride layer across the molten solvent. In one aspect, mixing a boron nitride source with a molten solvent includes applying the boron nitride source to a solidified solvent layer and heating the solidified solvent layer in a nitrogen atmosphere to melt the solidified solvent layer into a molten solvent such that the molten solvent and boron and nitrogen atoms from the boron nitride source form a eutectic liquid. In another aspect, precipitating the boron nitride source from the molten solvent includes maintaining the molten solvent and the boron nitride source in a eutectic liquid state to allow the hexagonal boron nitride layer to form across substantially all of the molten solvent. The boron nitride source can be any source of boron nitride known, including hexagonal boron nitride, cubic boron nitride, and the like. It should be noted that the scope of the present invention also includes hexagonal boron nitride materials made according to aspects described herein.

A variety of catalyst surface materials for the formation of hexagonal boron nitride are contemplated. For example, the catalyst surface can include a material such as Li, Na, K, Rb, Be, Mg, Ca, Sr, Ba, LiH, Li₃N, Na₃N, Mg₃N₂, Ca₃N₃, and alloys and combinations thereof. In one specific aspect, the catalyst surface can include Li₃N. In another specific aspect the catalyst surface can comprise substantially Li₃N, or may consist thereof.

It is also contemplated that the hexagonal boron nitride layer may be doped with a dopant. It should be noted that a variety of dopants can be included in the hexagonal boron nitride layer, depending on the desired properties of the resultant material. In one aspect, for example, the dopant can include an element such as Be, C, Si, Mg a combination of such elements. In one specific aspect the dopant can include Si. In another aspect, the dopant can be a metal atom.

In yet a further aspect, the present methods may be used to fabricate other compounds or materials besides graphene and hBN which primarily contain atoms bonded in a sp2 bonding configuration. In another aspect, such materials may be substantially comprised of atoms bonded in sp2 bonding configurations. In yet another aspect, such materials may consist or consist essentially of atoms bonded in sp2 configurations.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a graphical representation of a graphene lattice in accordance with one embodiment of the present invention.

FIG. 2 is a cross-sectional view of a mold assembly in accordance with another embodiment of the present invention.

FIG. 3 is a micrograph of a graphene layer in accordance with yet another embodiment of the present invention.

FIG. 4 is a micrograph of a graphene layer in accordance with a further embodiment of the present invention.

FIG. 5 is a micrograph of a graphene layer in accordance with yet a further embodiment of the present invention.

FIG. 6 is a micrograph of a graphene layer in accordance with another embodiment of the present invention.

FIG. 7 is a cross-sectional view of a mold assembly in accordance with yet another embodiment of the present invention.

### DETAILED DESCRIPTION OF THE INVENTION

### Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a particle” includes reference to one or more of such particles, and reference to “the material” includes reference to one or more of such materials.

As used herein, “degree of graphitization” refers to the proportion of graphite that has graphene planes having a theoretical spacing of 3.354 angstroms. Thus, a degree of graphitization of 1 indicates that 100% of the graphite has a basal plane separation (d₍₀₀₀₂₎) of graphene planes, i.e. with hexagonal network of carbon atoms, of 3.354 angstroms. A higher degree of graphitization indicates smaller spacing of graphene planes. The degree of graphitization, G, can be calculated using Equation 1.

G=(3.440−d₍₀₀₀₂₎)/(3.440−3.354) (1)

Conversely, d₍₀₀₀₂₎ can be calculated based on G using Equation 2.

d₍₀₀₀₂₎=3.354+0.086(1−G) (2)

Referring to Equation 1, 3.440 angstroms is the spacing of basal planes for amorphous carbon (L_{c}=50 Å), while 3.354 angstroms is the spacing of pure graphite (L_{c}=1000 Å) that may be achievable by sintering graphitizable carbon at 3000° C. for extended periods of time, e.g., 12 hours. A higher degree of graphitization corresponds to larger crystallite sizes, which are characterized by the size of the basal planes (Lₐ) and size of stacking layers (L_{c}). Note that the size parameters are inversely related to the spacing of basal planes. A “high degree of graphitization” or “highly graphitized” can depend on the materials used, but typically indicates a degree of graphitization greater than about 0.8. In some embodiments, a high degree of graphitization can indicate a degree of graphitization greater than about 0.85.

As used herein, “substantially less-reactive” refers to an element or a mixture of elements that does not significantly react with and chemically bond to graphene materials. Examples of substantially less-reactive elements may include, without limitation, gold (Au), silver (Ag), copper (Cu), lead (Pb), tin (Sn), zinc (Zn), and mixtures thereof.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This same principle applies to ranges reciting only one numerical value as a minimum or a maximum. Furthermore, such an interpretation should apply regardless of the breadth of the range or the characteristics being described.

### THE INVENTION

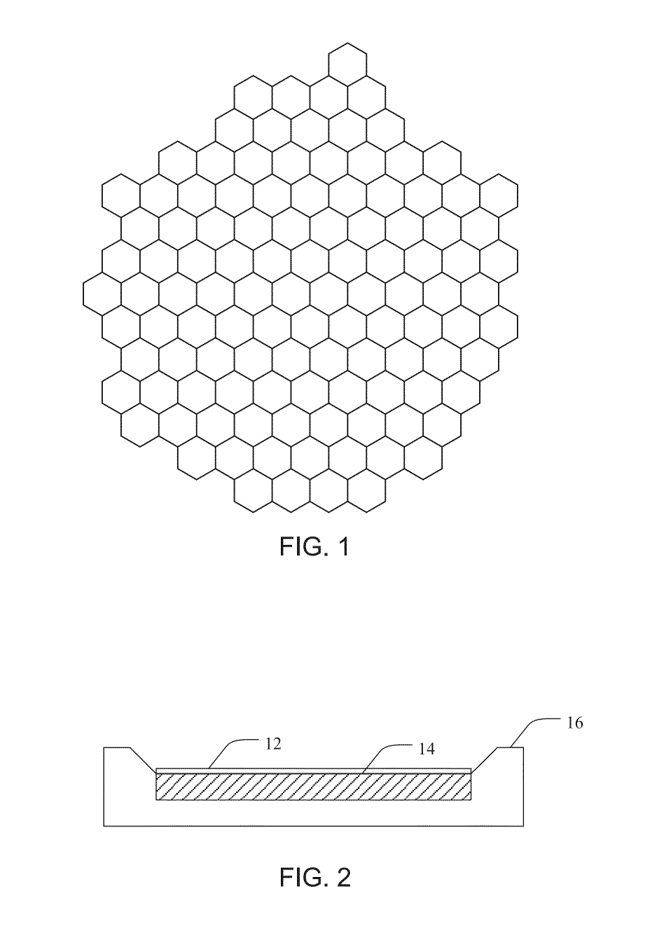

The present invention relates to novel graphene and hexagonal boron nitride layers and associated methods. Further it relates to methods for producing materials, and layers of materials, containing primarily atoms arranged in a sp2 bonding arrangement, as well as such materials. It has now been discovered that graphene layers may be produced that are of a sufficient size for use in many electronic applications. Graphene is a one-atom-thick planar sheet of sp2-bonded carbon atoms that are densely packed into a benzene-ring structure in a honeycomb crystal lattice, as is shown in FIG. 1. The carbon-carbon bond length in graphene is approximately 1.45 Å, which is shorter than that of diamond at 1.54 Å. Graphene is the basic structural element of other graphitic materials including graphite, carbon nanotubes, fullerenes, etc. It should be noted that the term “graphene” according to aspects of the present invention includes reference to both single atom layers of graphene and multiple layer stacks of graphene.

Perfect graphene planes consist exclusively of hexagonal cells, and any pentagonal or heptagonal cells within a graphene plane would constitute defects. Such defects alter the planar nature of the graphene layer. For example, a single pentagonal cell warps the plane into a cone shape, while 12 pentagons at the proper locations would create a fullerene of the plane. Also, a single heptagon warps the plane into a saddle-shape. Warpage of the graphene plane tends to reduce electron mobility and thermal conductivity, and thus may be undesirable for applications where these properties are valued.

As has been described, high quality graphene layers large enough to be useful in many electronic and other applications have proven difficult to obtain. It has now been discovered that large graphene layers can be created using a molten solvent. The materials making up the molten solvent function as a catalyst to aid in the sintering and/or formation of graphene flakes. In one aspect, for example, the present invention provides a method for forming a graphene layer. Such a method may include mixing a carbon source with a horizontally oriented molten solvent, precipitating the carbon source from the molten solvent to form a graphite layer across the molten solvent, and separating the graphite layer into a plurality of graphene layers. In some aspects, heating and precipitating of the carbon source can be accomplished under vacuum to minimize contamination.

Numerous methods of mixing the carbon source with the molten solvent are contemplated. In some cases, the carbon source can be mixed with an already molten solvent. In other cases, the carbon source can be associated with a solvent material that is then rendered molten. For example, in one aspect, mixing the carbon source with the molten solvent includes applying the carbon source to a solidified solvent layer, and heating the solidified solvent layer under vacuum to melt the solidified solvent layer into a molten solvent such that the molten solvent and carbon atoms from the carbon source form a eutectic liquid. The molten solvent and the carbon source can then be maintained in a eutectic liquid state to allow the graphite layer to form across substantially all of the molten solvent. In another aspect, methane can be pyrolyzed to form graphite on Ni sputtered on an alumina substrate. The Ni can then be heated to liquefy, and carbon atoms from the graphite can rearrange to form graphene.

In one aspect, graphene can be formed by exsolution of carbon from an oversaturated solution of carbon in the molten solvent. In such a case, the solvent liquid can be over saturated with the carbon material. The liquid can be cooled such that carbon begins to exsolve as kish graphite. The kish graphite floats on the top of the molten solvent surface, and is mended together to form high quality graphene. Vibration can be applied to the molten solvent to assist the mending of the graphite pieces. Such a process can allow efficient diffusion of carbon atoms in the oversaturated molten solvent and thus can readily precipitate around the edges of the “islands” of graphite flakes. Carbon atoms that have bonded in hexagonal arrangements are very stable, and thus are not easily dissolved by the molten solvent. The edges of such structures, on the other hand, contain dangling bonds that can be reactive with the solute atoms (e.g. Ni atoms). Thus the dissolution and precipitation is reversible along the edges, so the solute atoms repeatedly cycle through bonding and dissolving until the bonding of a carbon atom, resulting in growth around the edges of the flake. This process can be improved if the temperature is controlled near equilibrium, or if the temperature is cycled to dislodge unstable carbon atoms and solute atoms in favor of hexagonally bonded carbon.

In some aspects, an etchant can be utlized to remove carbon atoms and in some cases larger carbon molecules that are not fitting into the graphene lattice. Such etchants can include, without limitation, H, O, N, F, CL, and mixtures thereof. Additionally, methane can be applied across the surface as a supplemental carbon source, and to assist in mending graphene pieces into one at least substantially continuous layer. In one aspect, etchants and methane can be cycled over time to mend the graphene pieces into one at least substantially continuous layer. Additionally, the quality of the graphene layer can be improved by controlling the amount of floating graphene on the surface during mending. Too much graphene may cause the unmendable gaps in the forming layer, while too little graphene may significantly decrease production yield.

More specifically, as is shown in FIG. 2, a thin layer of highly graphitized graphite 12 can be spread across a solidified solvent layer 14 in a mold 16. The highly graphitized graphite can include natural graphite. In many cases, it may be beneficial to utilize a graphite material as the mold; however other materials would be useful as well, as would be recognized by one of ordinary skill in the art. Additionally, in one aspect the thin layer of highly graphitized graphite may be less than about 40 nm thick. In another aspect, the thin layer may be less than about 20 nm thick. It is also important to note that better results may be obtained when the highly graphitized graphite is highly purified. For example, various impurities of graphite such as oxygen and nitrogen may be removed by, for example, chlorination treatment at high temperature. Additionally, non-limiting examples of highly graphitized graphite include pyrolitic graphite, sputtered graphite, natural graphite, etc. In one aspect, the degree of graphitization of the graphite can be greater than about 0.80. In another aspect, the degree of graphitization of the graphite can be greater than about 0.90. In yet another aspect, the degree of graphitization of the graphite can be greater than about 0.95.

Following spreading of the graphite on the solidified solvent layer, the mold assembly can be heated in a vacuum furnace to melt the solvent material into a molten solvent. Upon melting, the solvent and the graphite form a eutectic liquid. For example, if the solvent is nickel, a eutectic liquid of Ni—C will form along the boundary between the molten solvent surface and the highly graphitized graphite. The molten solvent then facilitates the patching together of graphene flakes from the highly graphitized graphite into a continuous graphene layer. The molten solvent can be comprised of any material that will function to catalyze the formation of graphene. In one aspect, for example, the molten solvent may include Cr, Mn, Fe, Co, Ni, Ta, Pd, Pt, La, Ce, Eu, associated alloys, and combinations thereof. In one specific aspect, the molten solvent may include Ni. In another specific aspect, the molten solvent may be comprised substantially of Ni. In yet another aspect, the solvent may consist of, or consist essentially of Ni, or of Ni alloys. In one specific aspect, the molten solvent can include Fe, Ni, and Co. In one aspect, the molten solvent can initially be a powdered material brought into contact with the graphite material. In another aspect, the solidified solvent can be a hard surface onto which the graphite is deposited. The graphite could be applied to such a surface by a variety of methods, including dry powders, slurries, sputtering, etc.

In some cases the resulting graphene layer may become damaged due to the reactivity of solvents such as Ni with carbon. For example, carbide bonding can occur at the interface between the molten solvent and the graphite material. The strength of this bonding can cause the graphene layers to buckle and/or tear upon removal from the molten solvent surface. Accordingly, in some aspects a substantially less reactive compound or material can be included in the molten solvent in order to reduce the reactivity of the solvent with the graphite. Thus the reduction in reactivity of the solvent can reduce the amount of carbide formation along the interface, and thus facilitate the recovery of the graphene layers with a minimal of tearing.

Any material that can reduce the reactivity of the solvent while allowing the formation of graphene on the solvent surface should be considered to be within the scope of the present invention. In one aspect, the substantially less reactive compound can include elements such as Au, Ag, Cu, Pb, Sn, Zn, and combinations and alloys thereof. In one specific aspect, the substantially less reactive compound can be Cu. In yet another specific aspect, a Ni—Cu alloy may be used as a catalyst surface. For such an alloy, molten Ni can dissolve graphite due to the presence of empty 3d orbitals, while molten copper cannot because the 3d orbitals of this material are full. Ni—Cu is an alloy with a melting point adjustable between copper's 1084° C. to nickel's 1455° C., and thus the Ni—Cu alloy can be configured to optimize the reactivity between the liquid alloy and graphite flakes. This reactivity should not be strong to form carbide, but it should be strong enough to move carbon atoms in graphene, as to nudge them to the equilibrium positions where the energy is minimal. In another aspect, Cu—Mn may be utilized because Cu and Mn are fully miscible with a depression of melting point at 34.5 wt % of Mn with only 873° C.

Thus the making of graphene may be dependent on this unique mapping between graphene and liquid metal to allow the growth of graphene planes and to eliminate defect sites that are unstable due to catalytic reaction. In addition, the heavy molten liquid (density near 9 g/cc) can serve as the iron plane of the delicate graphene (density 2.5 g/cc). In this case, the hydrostatic balance can keep large areas of graphene flat by floating. In order to assist the movement of the defective carbon atoms, ultrasonic agitation may be applied to facilitate the sintering process and grain coarsening growth. The molten liquid can then be cooled in such a way that conspicuous grains do not form and buckle the already formed graphene. This can be accomplished by maintaining a temperature gradient to avoid the convection current and cool the top very slowly.

Without intending to be bound by any scientific theory, it is believed that the solvent material catalyzes the formation of the graphene layer because the size of the solvent atoms is much larger than the size of the carbon atoms. The empty d-orbitals of the solvent material can function to “nudge” or guide the carbon atoms into approximately the correct position for the carbon to form a graphene network. This interaction appears to not be strong enough for the formation of carbide to occur, but strong enough to facilitate the movement of carbon atoms. Thus the solvent liquid serves as a template for positioning carbon atoms to form the hexagonal graphene network. As the networks form, multiple layers of graphene can stack together with few if any grain boundaries. It should be noted that for multiple stacks of graphene, the further away from the catalyst surface that a graphene layer forms, the greater the chance that grain boundaries will begin to form.

Liquid nickel, for example, can align every other atom in a graphene layer as it forms. The mobile nature of the liquid template will nudge graphite atoms around so as to mend the interface between graphite flakes. There may be subtle details concerning the self assembly mechanism for auto mending graphite patches. This has to do with the two distinct sites of carbon atoms on graphene. Although an independent graphene plane assumes a hexagonal pattern, the multiple layers of graphite are slightly buckled with alpha sites and beta sites. Graphene planes shuffle to align only every other atoms (alpha site) to line up across planes. The other half of the population of atoms is located at the center of the neighboring hexagon. Because alpha sites are bonded by van der Waals force, their dangling electrons are too weak to interact with nickel atoms. Only beta sited carbon atoms are attracted to the vacancies of nickel's 3d orbitals. This means that graphene patches must oriented with respect to nickel atoms. In essence, this nudges the graphite flakes into alignment across the nickel surface.

Any grain boundaries in the graphene layer will thus be eliminated by the aforementioned catalytic effect of the molten solvent, thus forming a large area, high quality graphene layer having few if any grain boundaries. In some aspects, the graphene may have substantially none, or absolutely none grain boundaries. The graphene layer that is formed will often be essentially the same size as the surface upon which it was formed. The flat horizontal orientation of the melted solvent surface thus facilitates the formation of a graphene layer that is highly planar. It should be noted that this process may be utilized to form a single one atom thick graphene layer, or a graphene layer or plane having multiple individual graphene layers stacked in parallel. In the latter case, the stack of graphene layers will have a high electron mobility and a high thermal conductivity due to the multiple graphene layers having substantially no structural grain boundaries. In some cases, a thick layer of graphite is formed that can be separated into multiple graphene layers.

The temperature to which the mold assembly can be heated can vary depending on the nature of the solvent and the intended characteristics of the graphene product. In one aspect, however, the mold assembly can be heated to greater than about 1000° C. In another aspect, the mold assembly can be heated to greater than about 1300° C. In yet another aspect, the mold assembly can be heated to greater than about 1500° C. Similarly, graphene can be produced under a variety of pressures. In one aspect, for example, the pressure of the vacuum furnace can be less than about 5 Torr. In another aspect, the pressure of the vacuum furnace can be from about 10⁻³ to about 10⁻⁶ Torr.

Following the formation of the graphene layer, the mold assembly can be cooled to facilitate removal of the graphene product. In some aspects it may be beneficial to uniformly cool the surface to maintain the flatness of the surface. In one aspect such cooling may be accomplished by conducting heat from below the solvent surface and maintaining the heat above the solvent surface at a higher temperature. Once the solvent is cooled, graphene layers may be peeled from the surface. Graphene can be peeled away as single layers or as multiple layers. Such peeling can occur due to the 3.35 Å separation between the layers. Depending on the size of the solvent surface, graphene layers can be continuously peeled and rolled around a spooling device.

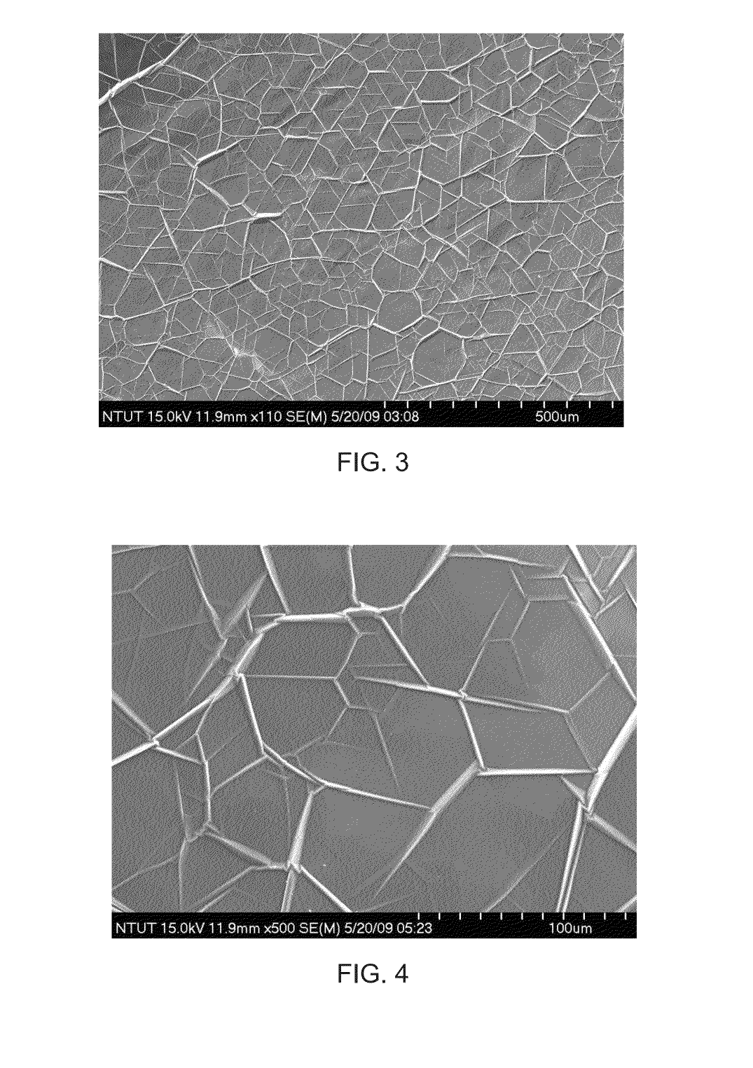

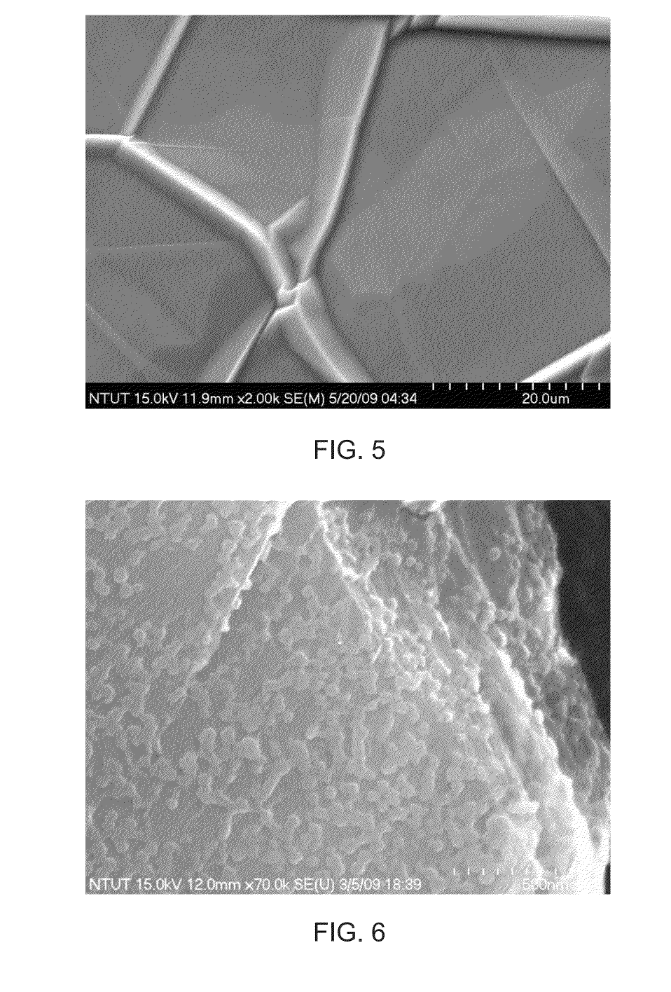

FIGS. 3-6 show micrographs of graphene layers formed as has is described herein. FIG. 3 shows a wrinkled graphite layer formed thereon. Graphene layers can be separated from this graphite layer as has been described. As can be seen in FIG. 4, the enlarged wrinkles show that the graphite layer is continuous without substantial cracking. FIG. 5 shows the flexibility of the graphite layer. FIG. 6 shows a dense distribution of microbes on an exposed graphene surface. The microbes on the graphene can be removed by heating to about 50° C. This is a reversible process, and as such, the graphene layers can be used as microbe sensors.

As has been described, in some cases graphene layers can be separated from thick graphite layers that have formed on the solvent surface. Numerous methods of separating these graphene layers are possible, all of which are encompassed within the scope of the present invention. In one aspect, the graphite layer can be heated in sulfuric acid. The intercalation of sulfur atoms can split the graphite film into numerous graphene layers. Each layer of graphene can subsequently be purified (e.g. in hydrogen or halogen at high temperature) to remove impurities and/or defects.

In another aspect of the present invention, defects can be eliminated using a gasification process. Because defects and grain boundaries in graphene layers are unstable, carbon atoms located at terminal positions are prone to be dissolved, while carbon atoms within the graphene network are relatively stable. Introducing heated oxygen or steam across the graphene surface will cause the unstable carbon atoms associated with the grain boundaries to be gasified into CO or CO₂. By controlling the CO/CO₂ ratio (partial pressure), carbon atoms can be removed at defective positions and grown into graphene flakes in an alternating fashion. In addition to oxygen, halogen gases such as F and Cl can also be utilized.

Graphene layers can additionally be grown through the thermal decomposition of carbonaceous gasses, such as methane, ethane, propane, butane, etc. Such a process can be utilized to grow high quality graphene due to the controlled solubility of carbon that avoids supersaturation of carbon and thus rapid uncontrolled growth. Thus a mixture of carbonaceous gasses such as CO/CO₂ can be added, and the partial pressures of CO and CO₂ can be varied in order to control the concentration of carbon in the molten solvent, thereby minimizing defects in the resulting graphene layers.

In some aspects of the present invention, graphene layers can be doped with a variety of dopants. Dopants can be utilized to alter the physical properties of a graphene layer, and/or they can be utilized to alter the physical interactions between graphene layers within a stack of graphene layers. Such doping can occur during formation of the graphene layer by adding the dopant to the molten solvent, or it can occur following the formation of the graphene layer by depositing the dopant in the layer. By doping with boron, for example, a P-type semiconductor is formed. A variety of dopants can be utilized for doping the graphene layers. Specific non-limiting examples can include boron, phosphorous, nitrogen, and combinations thereof. Doping can also be utilized to alter the electron mobility of specific regions of the graphene layer for the formation of circuits within the layer. Such site specific doping can allow the patterning of electrical circuits within a layer of graphene. Furthermore, while graphene layers have a high electron mobility, conductivity between graphene layers in a stack is more limited. By doping with metal atoms or other conductive materials, the electron mobility between stacked layers can be increased.

In addition to graphite and highly graphitized graphite, diamond materials can also be used as a carbon source in the formation of graphene layers. Diamond materials that can be used include natural, synthetic, single crystal, polycrystalline, DLC, amorphous diamond, and the like. One benefit of using such materials is the creation of graphene layers having a rhombohedral sequance (ABCABC . . . ) rather than the conventional ABABAB . . . sequence. Accordingly, in one aspect a method of forming a rhombohedral graphene layer can include mixing a diamond source with a horizontally oriented molten solvent and precipitating the diamond source from the molten solvent to form a rhombohedral graphene layer across the molten solvent.

The present invention additionally provides graphene layers made according to the processes described herein. Such layers may include single graphene layers or stacks of multiple graphene layers. Furthermore, as has been described, the graphene layers according to aspects of the present invention are high quality materials having few if any grain boundaries. Additionally, graphene layers can be produced according to aspects described herein that are of a greater size that has previously been possible due to the synthesis of the graphene material across the substantially all of the solvent or catalytic surface. While it should be understood that any size of graphene layer produced according to the methods of the present invention would be considered to be within the present scope, the methods of the present invention are particularly amenable to large area graphene layers. The size of such layers would necessarily vary depending on the size of the catalyst surface, however in one specific aspect the size of the graphene layer can be greater than about 1.0 mm². In another aspect, the size of the graphene layer can be from about 1.0 mm² to about 10 mm². In yet another aspect, the size of the graphene layer can be from about 10 mm² to about 100 mm². In a further aspect, the size of the graphene can be greater than about 100 mm². In yet another aspect, the size can be greater than about 10 cm². In a further aspect, the size can be greater than about 100 cm². In yet another aspect, the size can be greater than about 1 m².

The physical characteristics of graphene layers make it a beneficial material to incorporate into a variety of devices. Numerous devices and uses are contemplated, and the following examples should not be seen as limiting. For example, in one aspect, the high electron mobility of graphene makes it useful as a component of integrated circuits. In another aspect, graphene could be used as a sensor for single or multiple molecule detection, including gasses. The 2D structure of a graphene layer effectively exposes the entire volume of the graphene material to a surrounding environment, thus making it an efficient material for the detection of molecules. Such molecule detection can be measured indirectly: as a gas molecule adsorbs to the surface of graphene, the location of adsorption will experience a local change in electrical resistance. Graphene is a useful material for such detection due to its high electrical conductivity and low noise which makes this change in resistance detectable. In another aspect, a graphene layer may be utilized as a surface acoustic wave (SAW) filter. In this case a voltage signal can be transmitted due to the resonance of the graphene material. In yet another aspect, graphene may be utilized as a pressure sensor. In a further aspect, graphene layers may be utilized as transparent electrodes for LED, LCD, and solar panel applications. Additionally, graphene can be co-rolled with an insulative material such as a Mylar® film to produce a capacitor. Additionally, graphene can be co-rolled with insulative hexagonal boron nitride to produce an excellent capacitor material. Furthermore, graphene can be layered on a semiconductive material such as silicon, and etched to produce electrical interconnects for an electrical device.

The present application additionally provides hexagonal boron nitride layers and associated methods. In one aspect, for example, a method of forming a hexagonal boron nitride layer is provided. Such a method can include mixing a boron nitride source with a horizontally oriented molten solvent and precipitating the boron nitride source from the molten solvent to form a hexagonal boron nitride layer across the molten solvent. In one aspect, mixing the boron nitride source with a molten solvent includes applying the boron nitride source to a solidified solvent layer and heating the solidified solvent layer in a nitrogen atmosphere to melt the solidified solvent layer into a molten solvent such that the molten solvent and boron and nitrogen atoms from the boron nitride source form a eutectic liquid. In another aspect, precipitating the boron nitride source from the molten solvent includes maintaining the molten solvent and the boron nitride source in a eutectic liquid state to allow the hexagonal boron nitride layer to form across substantially all of the molten solvent.

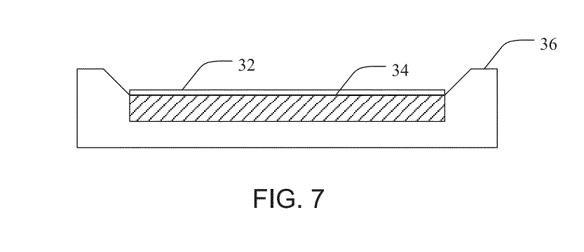

More specifically, as is shown in FIG. 7, a thin layer of boron nitride source such as flakes 32 can be spread across a solidified solvent layer 34 in a mold 36. In many cases, it may be beneficial to utilize a boron nitride material as the mold, however other materials would be useful as well, as would be recognized by one of ordinary skill in the art. Additionally, in one aspect the thin layer of boron nitride source may be less than about 40 nm thick. In another aspect, the thin layer may be less than about 20 nm thick.

Following spreading of the boron nitride on the solidified solvent layer, the mold assembly can be heated in a furnace with a nitrogen atmosphere to melt the solvent layer. The nitrogen atmosphere functions to suppress the evaporation of nitrogen from the boron nitride. Furthermore, the solubility of nitrogen in molten metal is much lower than boron. Nitrogen solubility can be increased by adding nitrogen getters such as Ni, Co, Fe, W, Mn, Mo, Cr, and combinations thereof. By increasing nitrogen solubility, the growth rate of the layer can be increased and the defect density can be decreased.

The catalytic surface thus facilitates the patching together of hexagonal boron nitride flakes from the boron nitride source into a continuous hexagonal boron nitride layer. The molten solvent can be comprised of any material that will function to catalyze the formation of a continuous hexagonal boron nitride layer. In one aspect, for example, the molten solvent can include Li, Na, K, Rb, Be, Mg, Ca, Sr, Ba, LiH, Li₃N, Na₃N, Mg₃N₂, Ca₃N₃, and alloys and combinations thereof. In one specific aspect, the catalyst surface may include Li₃N. In another specific aspect, the molten solvent can be comprised substantially of Li₃N. In yet another specific aspect, LiH may be used as a molten solvent.

Any grain boundaries in the hexagonal boron nitride layer will thus be eliminated by the catalytic effect of the molten solvent, thus forming a large area, high quality hexagonal boron nitride layer having few if any grain boundaries. The hexagonal boron nitride layer that is formed will be essentially the same size as the molten solvent upon which it was formed. The flat horizontal orientation of the molten solvent thus facilitates the formation of a hexagonal boron nitride layer that is highly planar. It should be noted that this process may be utilized to form a single one atom thick hexagonal boron nitride layer, or a hexagonal boron nitride layer or plane having multiple individual hexagonal boron nitride layers stacked in parallel. In the latter case, the stack of hexagonal boron nitride layers will have high electron mobility and a high thermal conductivity due to the multiple hexagonal boron nitride layers having substantially no structural grain boundaries.

The temperature to which the mold assembly can be heated can vary depending on the nature of the solvent and the intended characteristics of the hexagonal boron nitride product. In one aspect, however, the mold assembly can be heated to greater than about 1000° C. In another aspect, the mold assembly can be heated to greater than about 1300° C. In yet another aspect, the mold assembly can be heated to greater than about 1500° C. Similarly, hexagonal boron nitride can be produced under a variety of pressures. In one aspect, for example, the pressure of the nitrogen atmosphere in the furnace can be less than about 1 atm.

Following the formation of the hexagonal boron nitride layer, the mold assembly can be cooled to facilitate removal of the hexagonal boron nitride product. In some aspects it may be beneficial to uniformly cool the surface to maintain the flatness of the solvent surface. In one aspect such cooling may be accomplished by conducting heat from below the molten solvent and maintaining the heat above the molten solvent at a higher temperature. Once the solvent is cooled, hexagonal boron nitride layers may be peeled from the surface. Hexagonal boron nitride can be peeled away as single layers or as multiple layers. Depending on the size of the catalyst surface, hexagonal boron nitride layers can be continuously peeled and rolled around a spooling device.

In some aspects of the present invention, hexagonal boron nitride layers can be doped with a variety of dopants. Dopants can be utilized to alter the physical properties of a hexagonal boron nitride layer, and/or they can be utilized to alter the physical interactions between hexagonal boron nitride layers within a stack. Such doping can occur during formation of the hexagonal boron nitride layer by adding the dopant to the mold assembly, or it can occur following the formation of the hexagonal boron nitride layer by depositing the dopant in the layer. A variety of dopants can be utilized for doping the hexagonal boron nitride layers. Specific non-limiting examples can include silicon, Mg, and combinations thereof. Doping the hexagonal boron nitride with silicon results in an N-type semiconductor material.

The present invention additionally provides hexagonal boron nitride layers made according to the processes described herein. Such layers may include single hexagonal boron nitride layers or stacks of multiple hexagonal boron nitride layers. Furthermore, as has been described, the hexagonal boron nitride layers according to aspects of the present invention are high quality materials having few if any grain boundaries. Additionally, hexagonal boron nitride layers can be produced according to aspects described herein that are of a greater size that has previously been possible due to the synthesis of the hexagonal boron nitride material across the entire catalytic surface. While it should be understood that any size of hexagonal boron nitride layer produced according to the methods of the present invention would be considered to be within the present scope, the methods of the present invention are particularly amenable to large area hexagonal boron nitride layers. The size of such layers would necessarily vary depending on the size of the catalyst surface, however in on specific aspect the size of the hexagonal boron nitride layer can be greater than about 1.0 mm². In another aspect, the size of the hexagonal boron nitride layer can be from about 1.0 mm² to about 10 mm². In yet another aspect, the size of the hexagonal boron nitride layer can be from about 10 mm² to about 100 mm². In a further aspect, the size of the hexagonal boron nitride can be greater than about 100 mm². In yet another aspect, the size can be greater than about 10 cm². In a further aspect, the size can be greater than about 100 cm². In yet another aspect, the size can be greater than about 1 m².

The physical characteristics of hexagonal boron nitride layers make it a beneficial material to incorporate into a variety of devices. Numerous devices and uses are contemplated, and the following examples should not be seen as limiting. For example, in one aspect hexagonal boron nitride has a high band gap (5.97 eV) and can emit deep UV (about 215 nm wavelength). As such, hexagonal boron nitride can be utilized as an LED or solar cell. For example, these materials can have the shortest bond lengths (1.42 A) of solids, hence they can be harder than diamond in two dimensions. As a result, they possess very large band gap, capable of emitting deep ultraviolet. This may be very useful for nanometer lithography and UV excited phosphor to form white LEDs. P—N junctions may be formed for making transistors that can be formed in-situ with graphene interconnected circuits. In another example, graphene or mono BN also possess high sound speed and thermal conductivity. Because of this, they can be utilized as ultrahigh frequency surface acoustic wave filters, ultrasound generators, and heat spreaders. Due to the hexagonal symmetry, the materials are also piezoelectric. In other examples, graphene or BN layers can be used as sensors for chemisorbed gasses, delicate electrodes for analyzing PPB levels of ions (e.g. Pb) in water solutions by electrolysis, transparent electrodes with hydrogen termination, etc.

It should also be noted that hexagonal boron nitride can be similarly aligned by molten nickel. As has been described, liquid nickel can align every other atom in a graphene layer as it forms. The mobile nature of the liquid template will nudge graphite atoms around so as to mend the interface between graphite flakes. There may be subtle details concerning the self assembly mechanism for auto mending graphite patches. This has to do with the two distinct sites of carbon atoms on graphene. Although an independent graphene plane assumes a hexagonal pattern, the multiple layers of graphite are slightly buckled with alpha sites and beta sites. Graphene planes shuffle to align only every other atoms (alpha site) to line up across planes. The other half of the population of atoms is located at the center of the neighboring hexagon. Because alpha sites are bonded by van der Waals force, their dangling electrons are too weak to interact with nickel atoms. Only beta sited carbon atoms are attracted to the vacancies of nickel's 3d orbital's. This means that graphene patches are oriented with respect to nickel atoms. In essence, this nudges the graphite flakes into alignment across the nickel surface. In the case of hexagonal boron nitride, this orientational alignment is even more evident. This is because boron nitride layers are all matched in sites due to the complementary nature of electron short boron atoms and the nitrogen atoms. In the case of using nickel to catalyze the self assembly, nickel atoms with extra electrons will be pulled toward boron atoms due to the nature of empty 3d orbitals.

Hexagonal boron nitride has a very wide direct band gap that could emit deep UV by applying an electrical field. Hexagonal boron nitride is an intrinsic N-type semiconductor that can be further enhanced with Be or Mg doping. This cathode can be coupled with boron doped graphene of P-type to make IC or LED. These materials can self resonate, and thus can be used as a laser diode with a built in heat spreader.

A variety of devices are contemplated that incorporate hexagonal boron nitride and graphene layers. For example, hexagonal boron nitride layers have a high band gap, and are therefore good insulators. By alternating graphene and hexagonal boron nitride layers, an effective capacitative material is produced. This composite material can be produced in stacked, planar arrangements, or the layers can be rolled together in a composite cylindrical arrangement. Other potential uses include three dimensional integrated circuits of boron nitride transistors connected by graphene interconnects, batteries for cars, solar cells, notebooks, and cell phones. Parallel solar cells can be produced due to the thin cross section of this composite material. Further uses include gas and microbe sensors, as well as DNA and protein chips.

The present invention also provides graphene/hexagonal boron nitride composite materials. In one aspect, for example, an electrical precursor material can include a composite material comprising a graphene layer and a hexagonal boron nitride layer disposed on the graphene layer. In one specific aspect, the composite material comprises a plurality of alternating graphene layers and hexagonal boron nitride layers. These layers can be utilized in a variety of electronic components, as would be understood by one of ordinary skill in the art. By rolling the plurality of alternating layers into a cylindrical shape, for example, a useful cylindrical capacitor can be formed.

These composite materials can be made using the molten solvent methods disclosed herein, or by other methods of forming such layers. For example, in one aspect a method of making a graphene/hexagonal boron nitride composite material can include providing a template having a graphene layer disposed on a substrate, and depositing a boron nitride source material on the graphene layer to form a hexagonal boron nitride layer thereon. Thus the graphene layer is utilized during the deposition as a template for the hexagonal boron nitride layer. The hexagonal boron nitride layer can be deposited by any known method, including CVD and PVD processes.

One benefit that can be derived from the processes disclosed herein is the ability to manufacture graphene and hexagonal boron nitride having a predetermined size and shape. Because the material layers are formed across the surface of a molten solvent, the size and shape of the resulting graphene or hexagonal boron nitride layers can be determined by the size and shape of the horizontally oriented molten solvent. Hence, by preselecting a mold so as to produce a molten catalyst surface of a particular size and shape, the size and shape of the graphene or hexagonal boron nitride layers can also be predetermined. Such a predetermined size and shape is thus not merely the result of cutting a material layer to a particular shape, but rather, forming the material layer in a particular and preselected or predetermined size and shape.

In another aspect of the present invention, a method for forming silicon carbide layers is provided. Such a method can include mixing a silicon carbide source with a horizontally oriented molten solvent and precipitating the silicon carbide source from the molten solvent to form a silicon carbide layer across the molten solvent.

### EXAMPLE

### Example 1

A graphite block is machined to form a disk-shaped depression with a depth of about 3 mm. A pure nickel plate having a thickness of about 1 mm is placed in the depression. Ultra pure graphite is spread over the nickel plate, and the assembly is placed in a tube furnace. A vacuum is applied to the tube furnace to about 10⁻⁵ Torr. The nickel is then fully melted at 1500° C. The nickel maintained in the melted state for 30 to 60 minutes. The temperature is controlled such that the graphite side is about 50° C. hotter than the bath of the molten nickel. Such a temperature disparity reduces convection of the liquid that may disturb the formation of the forming graphene lattice. The furnace is then slowly cooled and the resulting graphene layer is then peeled from the cooled nickel plate.

### Example 2

A graphene layer is formed as in Example 1, with the exception that the nickel plated is electrolessly plated with a Ni—P layer. The eutectic point for a Ni—Ni₃P layer is 870° C., thus allowing the graphene planes to be formed at 1000° C.

### Example 3

A graphene layer is formed as in Example 1, with the exception that the ultra pure graphite is replaced with a blend of ultra pure graphite flakes and carbonyl nickel at 70 wt %.

### Example 4

Invar (Fe2Ni) powder is spread on the bottom of a graphite mold. A highly graphitized graphite (e.g. natural graphite) powder is spread along the top of the Invar powder. The mold assembly is heated under vacuum (e.g. 10̂−5 torr) to melt the alloy (e.g. 1300° C. for the eutectic composition of metal-carbon). Because graphite's density (2.25) is much lower than the density of the alloy (8-9), graphite flakes will float on top of the molten alloy. Moreover, due to the platelet shape of graphite, the graphene planes will be in parallel with the surface of molten alloy. In this case, the graphene flakes can be catalytically mended together by the iron alloy. This process is self assembling and self healing, so meter sized graphene planes can be formed.

After the growth of graphene planes, the molten bath can be cooled in such a way that the surface remains flat. This can be accomplished by conducting the heat from below with the top layer at a higher temperature. Once the assembly is cooled, graphene planes can be peeled away from the bottom layers that may stick to the alloy. Due to the large separation (3.35 A) between graphene planes, the peeling can be made with a continual process.

### Example 5

Purified natural graphite powder is mixed with 10 times its weight of Ni and Cu in equal proportion. The mixture is placed in a graphite mold and heated to 1300 C for 6 hours under vacuum. Graphite is dissolved and precipitated on the edges where dangling electrons are abundant. The resulting flakes float on the molten liquid. After 6 hours, the temperature is lowered to be between liquidus and solidus so that the liquid and solid are in equilibrium. During this stage, unstable carbon atoms are dissolved and more stable atoms are precipitated. The melt is then slowly solidified. The vacuum is purged with hydrogen to further remove graphite defects by gasifying carbon atoms. The enlarged graphite films are soaked in hot sulfuric acid to separate the graphene layers. The graphene layers are retrieved and mounted on a polished silicon wafer by wafer bonding at 800 C in vacuum. The surface is further purged with fluorine to remove any defects by forming CF₄ gas.

### Example 6

Purified hexagonal boron nitride (hBN) crystallites are mixed with lithium hydride under nitrogen atmosphere and heated above 1300 C to form solution of hBN. The melt is held at 1300 C for 6 hours and cooled to the temperature between liquidus and solidus. This eutectic melt is then slowly cooled and hydrogen is introduced to remove unstable B and N atoms. The hBN film so formed is boiled in hydrogen sulfuric acid to separate the layers. The retrieved hBN layers are mounted on the graphene coated silicon wafer of Example 5. A titanium film is deposited on the hBN layers by sputtering. The titanium film is etched to form interdigital transducers that can convert an electrical magnetic signal to surface acoustic waves, and vice versa.

### Example 7

hBN film is doped with beryllium to make it P-type. An AlN film is deposited on the hBN film by MBE and is doped with C atoms to form an N-type material. The resulting p-n junction is capable of UV emission upon receiving a DC input.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method of forming a graphene layer, comprising:
mixing a carbon source with a horizontally oriented molten solvent;
precipitating the carbon source from the molten solvent to form a graphite layer across the molten solvent; and
separating the graphite layer into a plurality of graphene layers.

2. The method of claim 1, wherein mixing the carbon source with the molten solvent includes:
applying the carbon source to a solidified solvent layer; and
heating the solidified solvent layer under vacuum to melt the solidified solvent layer into a molten solvent such that the molten solvent and carbon atoms from the carbon source form a eutectic liquid.

3. The method of claim 1, wherein precipitating the carbon source from the molten solvent includes maintaining the molten solvent and the carbon source in a eutectic liquid state to allow the graphite layer to form across substantially all of the molten solvent.

4. The method of claim 1, wherein the carbon source is highly graphitized graphite.

5. The method of claim 1, wherein the molten solvent includes a member selected from the group consisting of Cr, Mn, Fe, Co, Ni, Ta, Pd, Pt, La, Ce, Eu, associated alloys, and combinations thereof.

6. The method of claim 1, wherein the molten solvent includes Ni.

7. The method of claim 1, wherein the molten solvent includes a substantially less reactive compound that reduces the reactivity of the molten solvent as compared to the molten solvent without the substantially less reactive compound.

8. The method of claim 7, wherein the substantially less reactive compound is a member selected from the group consisting of Au, Ag, Cu, Pb, Sn, Zn, and combinations and alloys thereof.

9. The method of claim 7, wherein the substantially less reactive compound is Cu.

10. The method of claim 1, further comprising removing substantially all impurities from the graphite.

11. The method of claim 10, wherein the impurities include members selected from the group consisting of O, N, and combinations thereof.

12. The method of claim 1, further comprising doping the graphene layer with a dopant.

13. The method of claim 7, wherein the dopant is a member selected from the group consisting of B, P, N, metal atoms, and combinations thereof.

14. The method of claim 1, further comprising preselecting the size and shape of the horizontally oriented molten solvent to produce the plurality of graphene layers having a predetermined size and shape.

15. A graphene layer made by the process of claim 1, wherein the graphene layer has a predetermined size and shape.

16. The graphene layer of claim 15 incorporated into a device selected from the group consisting of, molecule sensors, LEDs, LCDs, solar panels, pressure sensors, SAW filters, resonators, transistors, capacitors, transparent electrodes, UV lasers, DNA chips, and combinations thereof.

17. The graphene layer of claim 15, wherein the graphene layer is coupled to a polished silicon wafer.

18. The graphene layer of claim 17, wherein the graphene layer is etched to form electrical interconnects.

19. A method of forming a hexagonal boron nitride layer, comprising:
mixing a boron nitride source with a horizontally oriented molten solvent; and
precipitating the boron nitride source from the molten solvent to form a hexagonal boron nitride layer across the molten solvent.

20. The method of claim 19, wherein mixing the boron nitride source with a molten solvent includes:
applying the boron nitride source to a solidified solvent layer; and
heating the solidified solvent layer in a nitrogen atmosphere to melt the solidified solvent layer into a molten solvent such that the molten solvent and boron and nitrogen atoms from the boron nitride source form a eutectic liquid.
